(19) United States
(12) Patent Application Publication
(10) Pub. No.: US 2011/0156219 A1
(43) Pub. Date: Jun. 30, 2011

(54) SEMICONDUCTOR DEVICE

(75) Inventors: Yoshitsugu KAWASHIMA, Kanagawa (JP); Masayuki HIROI, Kanagawa (JP); Hirofumi SAITO, Kanagawa (JP)

(73) Assignee: RENESAS ELECTRONICS CORPORATION, Kanagawa (JP)

(21) Appl. No.: 12/977,618

(22) Filed: Dec. 23, 2010

(30) Foreign Application Priority Data
Dec. 24, 2009 (JP) 2009-292937

(51) Int. Cl. H01L 23/544

(52) U.S. Cl. 257/620; 257/E23.179

(57) ABSTRACT

A semiconductor device is disclosed which can prevent interlayer cracking of interlayer dielectric films while improving the adhesion between the interlayer dielectric films in a dicing process using a dicing blade. In a scribing line area, dummy wirings are formed respectively in a blade area through which a dicing blade passes in a dicing process and in non-blade areas formed on both sides of the blade area and through which the dicing blade does not pass. In the non-blade areas, vertically adjacent dummy wirings are coupled together through dummy vias, while in the blade area the vertically adjacent dummy wirings are not coupled together through dummy vias.

### CROSS-REFERENCE TO RELATED APPLICATIONS

The disclosure of Japanese Patent Application No. 2009-292937 filed on Dec. 24, 2009 including the specification, drawings and abstract is incorporated herein by reference in its entirety.

### BACKGROUND OF THE INVENTION

The present invention relates to a semiconductor device and more particularly to the configuration of a scribe line area in a semiconductor device.

Recently, with the upgrade in performance of semiconductor devices, a technique for forming a so-called “low-k film (low dielectric constant insulating film) lower in relative dielectric constant than SiO₂ has been introduced in the semiconductor wafer diffusion process. The “low-k film” includes various types, which, however, are generally low in adhesion and mechanical strength. Consequently, there has been the problem that a crack developed in wafer dicing reaches a device-forming area with an internal circuit formed therein and exerts a bad influence thereon.

In Patent Document 1 (Japanese Unexamined Patent Publication No. 2006-005288) there is described a configuration wherein dummy wirings and dummy vias are coupled together in a scribing area. It is described therein that the propagation of a crack up to a seal ring portion can be suppressed thereby.

The following dummy pattern disposing method is described in Patent Document 2 (Japanese Unexamined Patent Publication No. 2004-235357). Square, “keima” (a knight in shogi or chess)-like arranged dummy patterns capable of being generated in high uniformity at the time of automatic generation are formed in the interior of a chip, while lattice-like arranged rectangular dummy patterns having a high chipping resistance are formed over a scribing line. In multi-layer interconnection, dummy patterns over a scribing line in different wiring layers are coupled together through vias.

In Patent Document 3 (Japanese Unexamined Patent Publication No. Hei 10 (1998)-335333) is described a configuration wherein dummy wirings are provided in a scribing area. It is described therein that the flatness of an insulating film polished by the CMP method can be improved thereby.

In Patent Document 4 (Japanese Unexamined Patent Publication No. 2008-066716) is described a configuration wherein the percent occupancy per unit area of first dummy patterns arranged in a cutting area of a scribing area is smaller than that of second dummy patterns arranged in a non-cutting area. It is described therein that not only dishing in the CMP process can be prevented thereby, but also clogging of a dicing blade in wafer dicing can be thereby diminished to prevent the occurrence of a chipping defect.

### SUMMARY OF THE INVENTION

However, the present inventors have found out that for example in case of providing dummy wirings in all layers in a scribing line area and coupling them through dummy vias, dummy metal structures become very large, giving rise to a problem. As will be described later, as the dummy metal structures become very large, cutting chips produced at the time of cutting with a dicing blade also become very large. As a result, in the cutting process using a dicing blade, chips resulting from cutting and having become very large are rolled in between side walls of a cut face and the dicing blade and cracks are developed suddenly in the side walls.

There also is a problem that if dummy metal structures functioning as a wedge are not present in the scribing line area, the adhesion between interlayer dielectric films in dicing with a dicing blade is deteriorated. For example, as described in Patent Document 4, even with a seal ring provided, if delamination occurs in the scribing line area, the delamination cannot be stopped at the seal ring, but may be propagated up to a device-forming area.

According to an aspect of the present invention, there is provided a semiconductor device comprising a substrate, a plurality of wiring layers formed over the substrate, the wiring layers including a first wiring layer and a second wiring layer formed over the first wiring layer, and a multi-layer interconnection including a plurality of via layers, the via layers including a first via layer formed between the first wiring layer and the second wiring layer, in which:

over the substrate are formed a plurality of device-forming areas, a plurality of seal ring areas each including a seal ring disposed so as to surround the device-forming area associated with the seal ring area, and a scribing line area disposed so as to surround each of the seal ring areas at an outer periphery of the seal ring area,

the scribing line area including a blade area for passing therethrough of a dicing blade in a dicing process and a non-blade area with the dicing blade not passing therethrough,

in the blade area are formed a first dummy wiring, the first dummy wiring being formed in the first wiring layer, and a second dummy wiring, the second dummy wiring being formed over the first dummy wiring in the second wiring layer,

in the non-blade area are formed a third dummy wiring, the third dummy wiring being formed in the first wiring layer, a fourth dummy wiring, the fourth dummy wiring being formed over the third dummy wiring in the second wiring layer, and a first dummy via for coupling the third dummy wiring and the fourth dummy wiring with each other in the first via layer, and

in the first via layer, a dummy via is not formed in the blade area.

According to this configuration, in the blade area through which a dicing blade passes in the dicing process, there are provided dummy metal structures wherein dummy wirings are not coupled continuously through dummy vias. Therefore, when cutting the substrate with a dicing blade, each dummy metal structure comes to pieces, whereby chips resulting from the cutting operation can be made small. Consequently, the chips can be prevented from being rolled in between a cut face of an interlayer dielectric film and side walls of the cut face and hence it is possible to prevent cracking. In this configuration, moreover, in the non-blade area of the scribing line area there are provided via-containing dummy metal structures with dummy wirings coupled through dummy vias. Since the via-containing dummy metal structures function as a wedge, it is possible to improve the adhesion between plural interlayer dielectric films in a multi-layer interconnection and hence possible to prevent the occurrence of delamination in the scribing line area. As a result, it is also possible to prevent the delamination from being propagated up to the device-forming areas.

Arbitrary combinations of the above constituent elements and expressional modifications of the present invention with respect to method and apparatus are also effective as modes of the present invention.

According to the present invention it is possible to prevent interlayer cracking of interlayer dielectric films while improving the adhesion between the interlayer dielectric films at the time of dicing with a dicing blade.

### BRIEF DESCRIPTION OF THE DRAWINGS

FIG. 1 is a sectional view showing an example of configuration of a semiconductor device according to an embodiment of the present invention;

FIG. 2 is a plan view showing the configuration of the semiconductor device embodying the present invention;

FIG. 3 is an enlarged plan view showing the configuration of an area enclosed with a broken line in FIG. 2;

FIG. 4 is an enlarged plan view showing the configuration of an area enclosed with a broken line in FIG. 3;

FIG. 5 is an enlarged sectional view showing the configuration of an area A and that of an area B each enclosed with a broken line in FIG. 1;

FIG. 6 is a plan view showing a layout relation among dummy wirings;

FIG. 7 is a sectional view showing the configuration of a semiconductor device according to a modification of the semiconductor device of the embodiment;

FIG. 8 is an enlarged sectional view showing the configuration of an area A and that of an area B each enclosed with a broken line in FIG. 7;

FIG. 9 is an enlarged sectional view showing configurations corresponding to the broken-line areas A and B in FIG. 7 in the configuration of another modification of the semiconductor device of the embodiment;

FIG. 10 is a sectional view for schematically explaining the effect of the configuration of the semiconductor device embodying the present invention; and

FIG. 11 is a sectional view for schematically explaining a problem encountered in the case where via-containing dummy metal structures with dummy wirings coupled together through dummy vias are provided in all the layers of a scribing line area.

### DETAILED DESCRIPTION OF THE PREFERRED EMBODIMENTS

An embodiment of the present invention and modifications thereof will be described below with reference to the accompanying drawings. In all the drawings, the same constructional elements are identified by the same reference numerals, and explanations thereof will be omitted.

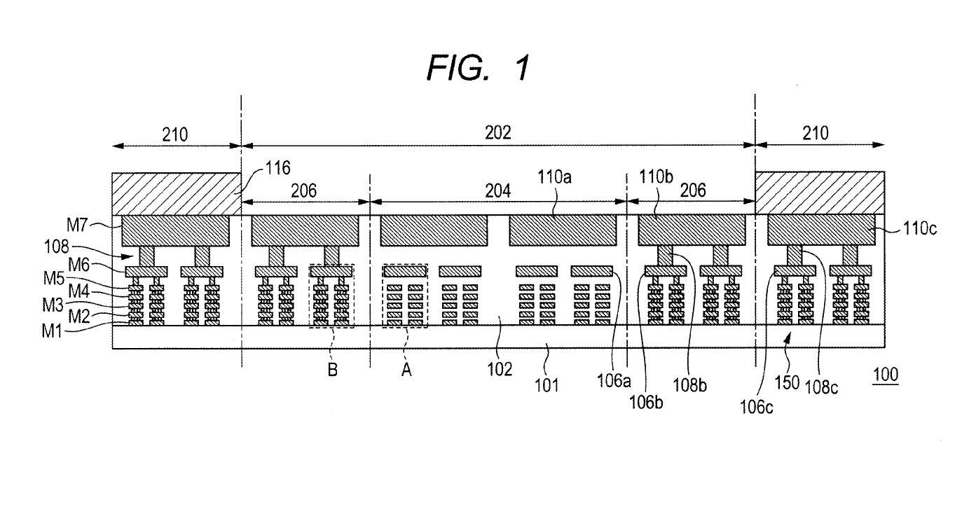

FIG. 1 is a sectional view showing the configuration of a semiconductor device according to an embodiment of the present invention.

A semiconductor device 100 includes a substrate 101, a multi-layer interconnection formed on the substrate 101 and a polyimide film 116 (protective film) formed on the multi-layer interconnection. The multi-layer interconnection includes a plurality of wiring layers M1, M2, M3, M4, M5, M6 and M7, which are stacked in this order from below, as well as a plurality of via layers each formed between adjacent such wiring layers. Here, for the purpose of explanation, the via layer located between the wiring layers M6 and M7 is shown distinctively as a via layer 108. Each wiring layer includes an interlayer dielectric film and wirings formed in the interlayer dielectric film. Each via layer includes an interlayer dielectric film and vias formed in the interlayer dielectric film. The substrate 101 may be a semiconductor substrate such as a silicon substrate. Here the substrate 101 is still in the state of a wafer not subjected to package dicing yet.

Although in FIG. 1 the interlayer dielectric films 102 are depicted all together as a single film, the interlayer dielectric films 102 may be, for example, stacked films of plural interlayer dielectric films provided respectively for wiring layers, for via layers, or for dual damascene wiring layers as integral wiring-via layers. The interlayer dielectric films 102 may include a low dielectric constant interlayer dielectric film.

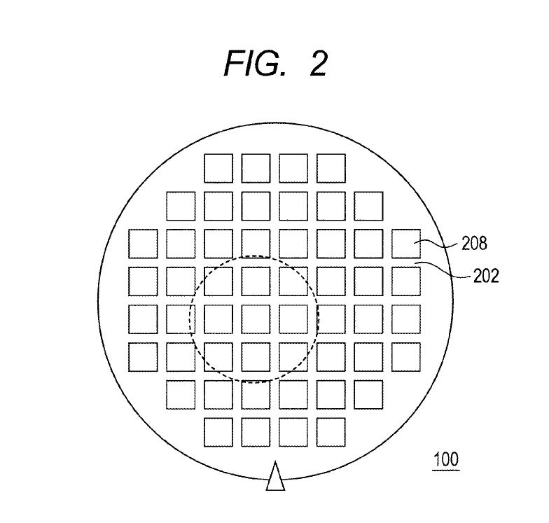

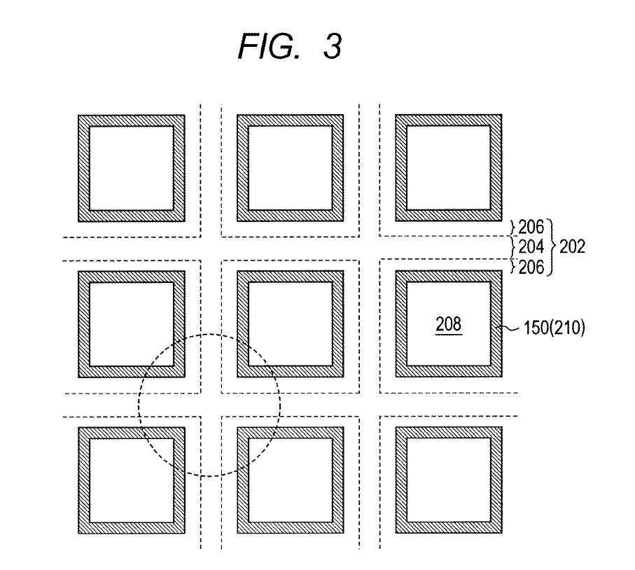

FIG. 2 is a plan view showing the configuration of the semiconductor device 100. The semiconductor device 100 includes a plurality of device-forming areas 208 each formed with an internal circuit and a scribing line area 202 formed around the device-forming areas 208. FIG. 3 is an enlarged plan view showing the configuration of an area enclosed with a broken line in FIG. 2. Between each device-forming area 208 and the scribing line area 202 is formed a seal ring area 210 including a seal ring 150 which is formed so as to surround the device-forming area 210. The scribing line area 202 is formed at an outer periphery of the seal ring 210 so as to surround the sealing ring.

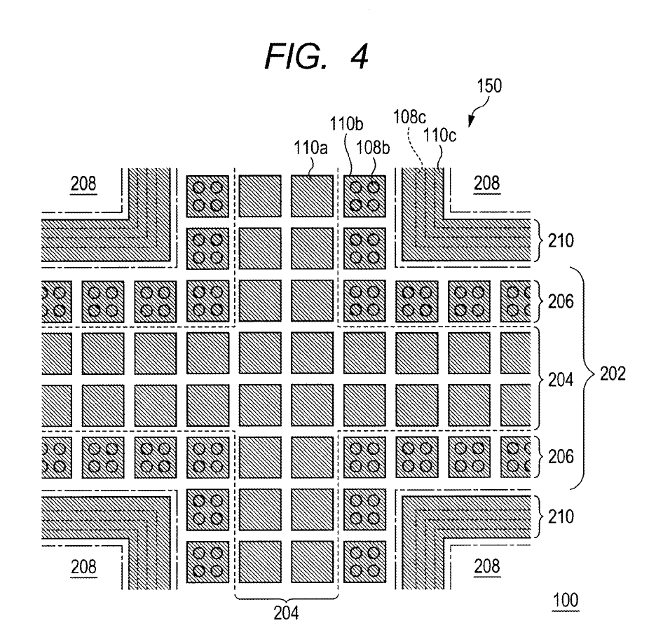

FIG. 4 is an enlarged plan view showing the configuration of an area enclosed with a broken line in FIG. 3. The following description is now provided with reference to FIGS. 1 to 3.

In a dicing process, the scribing line area 202 in the semiconductor device 100 configured as above is cut with a dicing blade to divide the semiconductor device 100 into individual chips. The scribing line area 202 includes a blade area 204 through which the dicing blade actually passes in the dicing process and non-blade areas 206 formed on both sides of the blade area 204 and through which the dicing blade does not pass.

The blade area 204, taking a positional deviation in the cutting operation into account, may have a slight marginal space in the actually passing area of the dicing blade. As an example, in the case where the width of the scribing line area 202 is about 100 μm and the width of the area through which the dicing blade actually passes is about 45 μm, a marginal width of about 5 μm may be formed on each of both sides of the actually passing area of the dicing blade and hence the width of the blade area 204 may be made 55 μm or so.

As shown in FIG. 1, although the polyimide film 116 is formed on the seal ring area 210, it is not formed on the scribing line area 202. The polyimide film 116 is also formed on each device-forming area 208. By forming a protective film superior in both heat resistance and chemicals resistance such as for example the polyimide film 116 on both device-forming area 208 and seal ring area 210, both areas 208 and 210 can be protected. However, also in the seal ring area 210 and the device-forming area 208, the polyimide film 116 may be removed selectively in connections, e.g., pads, for coupling with external terminals.

The following description is now provided with reference as an example to the wiring layers M6, M7 and the via layer 108 formed between both wiring layers. In the blade area 204, dummy wirings 106a (first dummy wirings) are formed in the wiring layer M6, while in the wiring layer M7, dummy wirings 110a are formed over the dummy wirings 106a. In the non-blade areas 206, dummy wirings 106b (third dummy wirings) are formed in the wiring layer M6, while in the wiring layer M7, dummy wirings 110b (fourth dummy wirings) are formed over the dummy wirings 106b. In the via layer 108 between the wiring layers M6 and M7, dummy vias 108b (first dummy vias) for coupling between the dummy wirings 106b and 110b are formed in the non-blade area 206. On the other hand, in the via layer 108, dummy vias are not formed in the blade area 204.

In the seal ring area 210, dummy wirings 106c are formed in the wiring layer M6, while in the wiring layer M7, dummy wirings 110c are formed over the dummy wirings 106c. In the seal ring area 210, moreover, dummy vias 108c for coupling between the dummy wirings 106c and 110c are formed in the via layer 108 between the wiring layers M6 and M7.

In this embodiment, in all of the blade area 204, non-blade areas 206 and seal ring area 210, dummy wirings may be provided in all the layers from the wiring layer M1 to the wiring layer M7.

In the seal ring area 210, the seal ring 150 may be formed continuously in all the layers of the multi-layer interconnection. That is, in the seal ring area 210, vertically adjacent dummy wirings may be coupled together through dummy vias in all the layers of the multi-layer interconnections. Further, in each of the layers in the multi-layer interconnection, the seal ring 150 may be formed so as to continuously surround each device-forming area 208. For example, as shown in FIG. 4, in the seal ring area 210, the dummy vias such as the dummy vias 108c may each be formed as a slit via which continuously surrounds each device-forming area 208. In the seal ring area 210, moreover, the dummy wirings such as the dummy wirings 110c may also be formed rectilinearly, surrounding each device-forming area 208 continuously. According to this configuration, water or the like can be prevented from getting into the device-forming areas 208 from the exterior.

According to this embodiment, in the non-blade areas 206, as in the seal ring area 210, vertically adjacent dummy wirings may be coupled together through dummy vias in all the layers of the multi-layer interconnection. On the other hand, there may be adopted a configuration such that, in the blade area 204, dummy vias are not formed in any of the layers of the multi-layer interconnection.

According to this embodiment, in the non-blade areas 206 of the scribing line area 202, dummy wirings and dummy vias may be arranged dispersedly in each of the layers of the multi-layer interconnection. Also in the blade area 204 of the scribbling line area 202, dummy wirings may be arranged dispersedly in each of the layers of the multi-layer interconnection. For example, as shown in FIG. 4, in he blade area 204 and the non-blade areas 206, dummy wirings 110a and 110b may be formed in a rectangular shape or dot shape in plan and may be dispersed for example in a matrix shape. Also in the non-blade areas 206, dummy vias such as the dummy vias 108b may be formed in a columnar shape of a circular section in plan and may be dispersed for example in a matrix shape.

In this embodiment, the layout, density and size of dummy wirings and dummy vias in each layer of the multi-layer interconnection may be set suitably. For example, in all or part of the layers in the multi-layer interconnection, the dummy wirings formed in the blade area 204 and those formed in the non-blade areas 206 may be made substantially equal in layout density to each other.

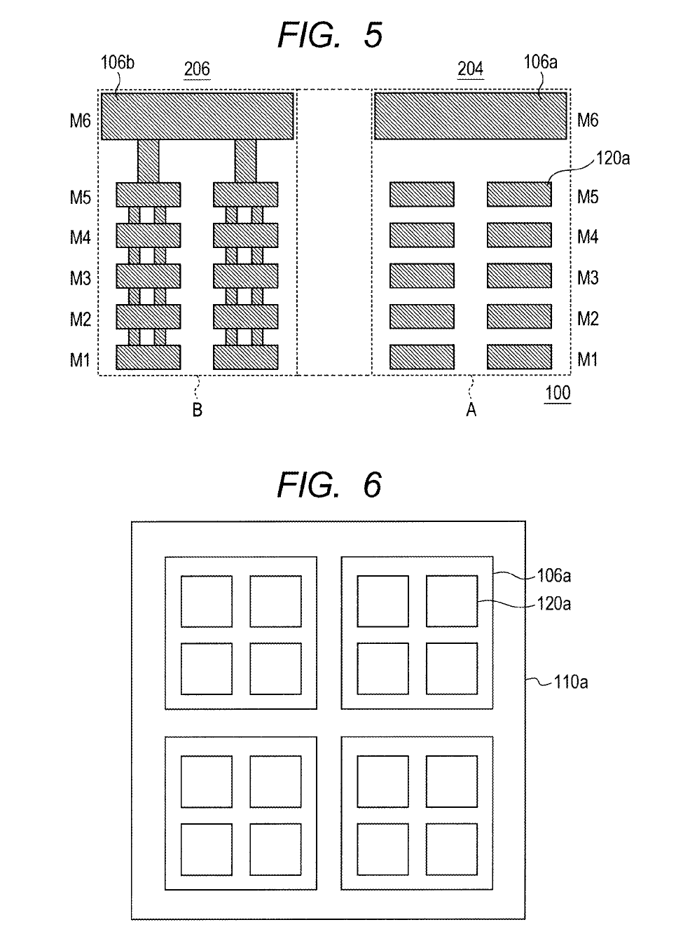

FIG. 5 is an enlarged sectional view showing the configurations of areas A and B each enclosed with a broken line in FIG. 1. FIG. 6 is a plan view showing a layout relation among a dummy wiring 110a, dummy wirings 106a, and dummy wirings 120a formed in the wiring layer M5 and underlying the dummy wirings 106a. Only outer edges of the dummy wirings are illustrated in the figures in order to explain the shape of each dummy wiring and a layout relation among the dummy wirings.

Next, a description will be given below about the effect of the semiconductor device 100 according to this embodiment.

As noted previously, the present inventors have found out that in case of providing wirings in all the layers in the scribing line area and coupling them through vias, the dummy metal structures become very large, giving rise to a problem. This point will be explained below with reference to drawings.

FIG. 11 is a sectional view for schematically explaining a problem encountered in the case where via-containing dummy metal structures 310 with dummy wirings coupled together through dummy vias are provided in all the layers in the scribing line area 202. According to the illustrated configuration, also in the portion cut by a dicing blade 300, chips resulting from cutting with the dicing blade 300 become very large because the via-containing dummy metal structures 310 become very large. Consequently, as shown in the same figure, the chips resulting from the cutting operation, which have become very large, are rolled in between side walls of a cut face of the interlayer dielectric film 102 and the dicing blade 300 and cracks are developed suddenly in the side walls due to clogging of the dicing blade 300. Upon development of such cracks, a certain degree of crack reaches the associated device-forming area, causing a trouble that the chip mounted in the device-forming area fails to operate.

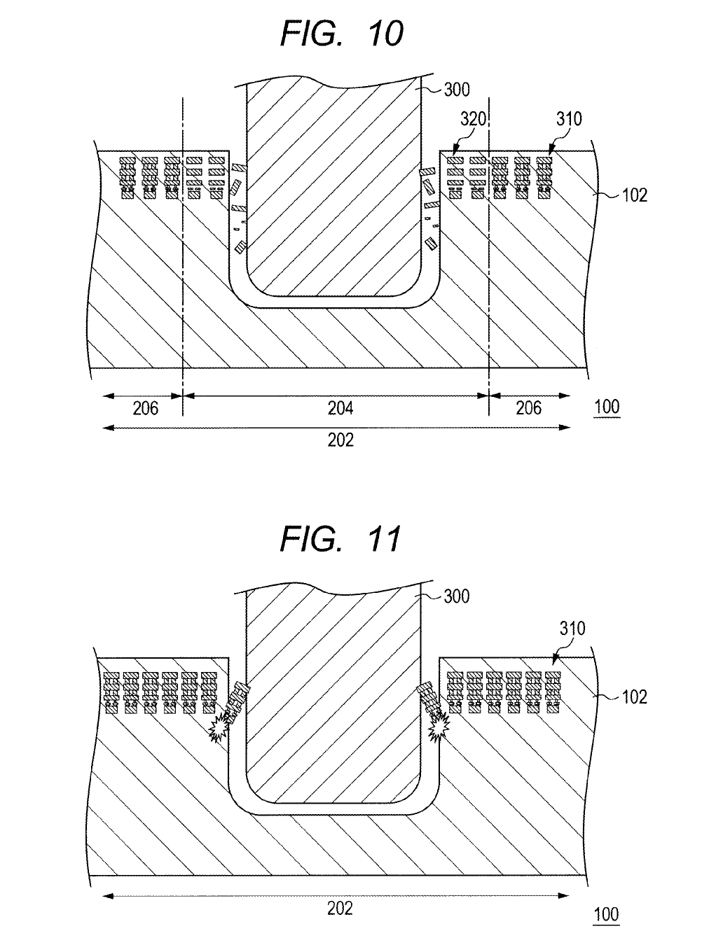

On the other hand, FIG. 10 is a sectional view for schematically explaining the effect obtained by the configuration of the semiconductor device 100 of this embodiment. According to this embodiment, in the blade area 204 through which the dicing blade passes in the dicing process, there are provided via-free dummy metal structures 320 with dummy wirings not coupled through dummy vias. Therefore, at the time of cutting the substrate with the dicing blade 300, the dummy wirings come to pieces and hence chips resulting from the cutting operation can be made small. Consequently, the chips resulting from the cutting operation can be prevented from being rolled in between the side walls of the cut face of the interlayer dielectric film 102 and the dicing blade 300 and hence it is possible to prevent cracking.

On the other hand, if the via-free dummy metal structures 320 are provided throughout the whole of the scribing line area 202, there is a fear that delamination may occur in the scribing line area 202. As described in Patent Document 4, once delamination occurs in the scribing line area 202, the delamination cannot be stopped at the seal ring and may be propagated up to the associated device-forming area. According to this embodiment, in the non-blade areas 206 close to the blade area 204 in the scribing line area 202, there are provided via-containing dummy metal structures 310 with dummy wirings coupled through dummy vias. Therefore, at the time of dicing, the via-containing dummy metal structures 310 function as a wedge in close proximity to the passage of the dicing blade 300, so that the adhesion between adjacent interlayer dielectric films in the multi-layer interconnection can be improved and it is possible to prevent the occurrence of delamination in the scribing line area 202. Consequently, it is also possible to prevent delamination from being propagated up to the device-forming area 208.

In the semiconductor device 100 of this embodiment, it suffices to merely provide a reticle lest dummy vias should be formed in the blade area 204 when forming dummy vias in the seal ring areas 210 and non-blade areas 206. Thus, the semiconductor device 100 can be manufactured in a simple manner without the addition of any new step.

Next, a description will be given about a modification of the semiconductor device 100 described above. According to this modification, the multi-layer interconnection may include a configuration wherein also in the blade area 204 vertically adjacent dummy wirings are coupled together through dummy vias. Also in this case, in some layers in the blade area 204, vertically adjacent dummy wirings may not be coupled together through dummy vias. In the blade area 204, though not specially limited, in case of coupling dummy wirings through dummy vias, the number of layers in which dummy wirings are coupled continuously may be set three or less lest dummy wirings should be coupled continuously through dummy vias in four or more layers.

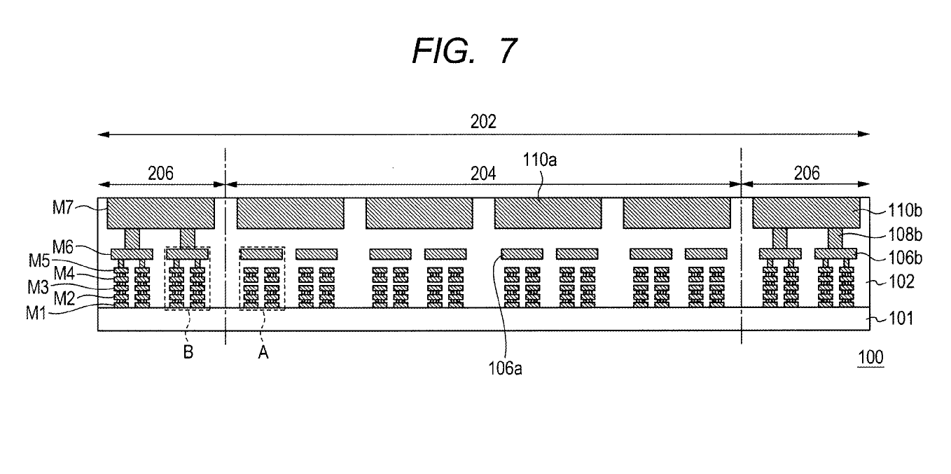

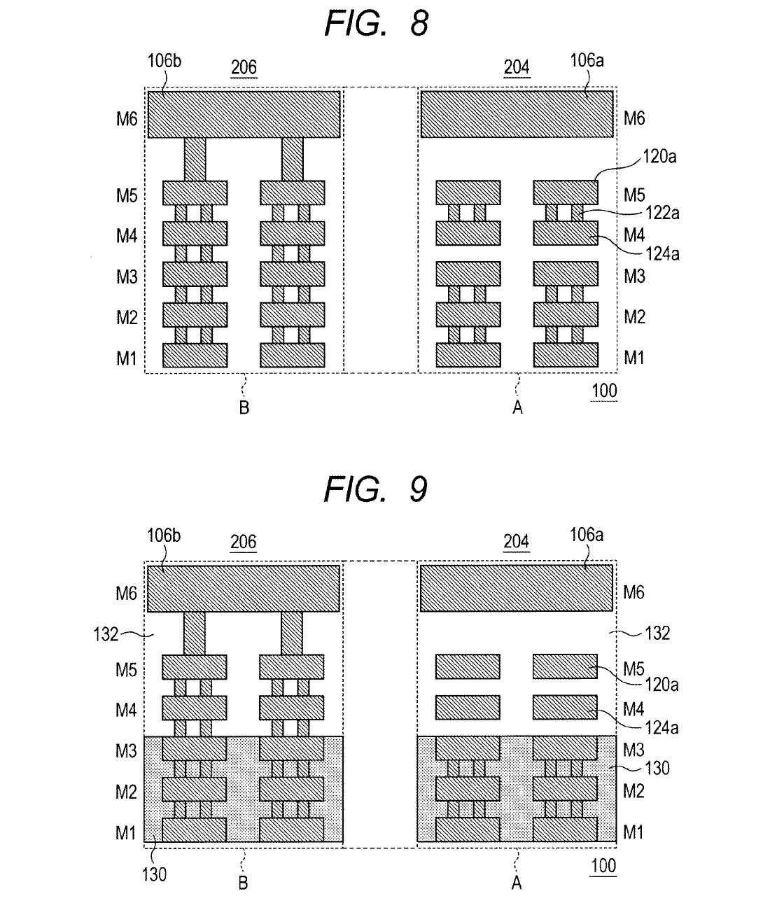

FIG. 7 is a sectional view showing a modification of the configuration of the semiconductor device 100 shown in FIG. 1. In this figure, illustration of the seal ring area 210 is omitted. FIG. 8 is an enlarged sectional view showing the configurations of areas A and B each enclosed with a broken line in FIG. 7.

In this modification, the configuration of the area B in each non-blade area 206 is the same as the configuration of the area B shown in FIGS. 1 and 5, provided the configuration of the area A in the blade area 204 is different from that shown in FIGS. 1 and 5. According to this modification, in some layers also in the blade area 204, vertically adjacent dummy wirings are coupled through dummy vias. In this point the configuration of this modification is different from that shown in FIGS. 1 and 5.

In the blade area 204, dummy wirings 120a provided in the wiring layer M5 and dummy wirings 124a provided in the wiring layer M4 are coupled together through dummy vias 122a provided in the via layer between the wiring layers M5 and M4. Dummy wirings provided in the wiring layers M1 and M2 are also coupled together through dummy vias provided in the via layer between them. Likewise, dummy wirings provided in the wiring layers M2 and M3 are coupled together through dummy vias provided in the via layer between them. On the other hand, also in this modification, dummy vias are not formed for example in the via layer between the wiring layers M3 and M4, in the via layer between the wiring layers M5 and M6, and further in the via layer between the wiring layers M6 and M7. Consequently, the associated via-containing dummy metal structures can be made small. As a result, similarly to the above explanation made with reference to FIG. 10, chips resulting from the cutting operation can be prevented from being rolled in between side walls of a cut face of the interlayer dielectric film 102 and the dicing blade 300 and hence it is possible to prevent the occurrence of cracks.

FIG. 9 is an enlarged sectional view showing configurations corresponding to the areas A and B each enclosed with a broken line in FIG. 7 according to another modification of the semiconductor device of the embodiment.

In this modification, the configuration of the area B in the non-blade area 206 is the same as the configuration of the area B shown in FIGS. 1 and 5. On the other hand, the configuration of the area A in the blade area 204 is different from the configuration shown in FIGS. 7 and 8. Also in this modification, like the configuration shown in FIGS. 7 and 8, in some layers even in the blade area 204, vertically adjacent dummy wirings are coupled together through dummy vias.

In this modification, wiring layers M1, M2 and M3 are configured by a low dielectric constant interlayer dielectric film 130, while the overlying layers are configured by an interlayer dielectric film 132 which is not the low dielectric constant interlayer dielectric film, e.g., a silicon oxide film. The low dielectric constant interlayer dielectric film 130 may be set to a relative dielectric constant of, say, 2.9 or less. In such a configuration, also in the blade area 204, underlying dummy wirings may be coupled together through dummy vias at the portion configured by the low dielectric constant interlayer dielectric film 130. On the other hand, in the blade area 204, dummy vias may not be provided at the portion configured by the interlayer dielectric film 132.

According to such a configuration, in the low dielectric constant interlayer dielectric film 130 not so high in adhesion, dummy wirings may be coupled together through dummy vias also in the blade area 204 to improve the layer-to-layer adhesion, while in the other layers dummy wirings are not coupled together through dummy vias to prevent dummy metal structures from becoming too large.

Although an embodiment of the present invention and modifications thereof have been described above with reference to the drawings, these are mere illustrations of the present invention and various other configurations than the above may also be adopted.

What is claimed is:

1. A semiconductor device comprising:
a device-forming area formed over a substrate,
a seal ring area including a seal ring disposed so as to surround the device-forming area,
a scribing line area disposed so as to surround the seal ring area at an outer periphery of the seal ring area, the scribing line area including a blade area for passing therethrough of a dicing blade in a dicing process and a non-blade area with the dicing blade not passing therethrough,
a plurality of wiring layers formed on the scribing line area, the wiring layers including a first wiring layer and a second wiring layer formed in the first wiring layer,
a multi-layer interconnection including a plurality of via layers, the via layers including a first via layer formed between the first wiring layer and the second wiring layer,
a first dummy wiring formed in the first wiring layer in the blade area,
a second dummy wiring formed over the first dummy wiring formed in the second wiring layer in the blade area,
a third dummy wiring formed in the first wiring layer in non-blade area,
a fourth dummy wiring formed over the third dummy wiring in the second wiring layer in non-blade area, and
a first dummy via connecting the third dummy wiring and the fourth dummy wiring in the first via layer in the non-blade area,
wherein in the first via layer, a dummy via is not formed in the blade area.

2. The semiconductor device according to claim 1, wherein the multi-layer interconnection includes a low dielectric constant interlayer dielectric film.

3. The semiconductor device according to claim 1, wherein in each of the wiring layers in the multi-layer interconnection, dummy wirings are formed in the blade area and the non-blade area, respectively.

4. The semiconductor device according to claim 3, wherein in the non-blade area, the dummy wirings adjacent to one another vertically are coupled together through dummy vias in all the layers of the multi-layer interconnection.

5. The semiconductor device according to claim 1, wherein in the device-forming areas and the seal ring areas, a protective film formed over the multi-layer interconnection is further included, the protective film being not formed over the scribing line area.

6. The semiconductor device according to claim 1, wherein the seal rings are formed continuously in all the layers of the multi-layer interconnection.

7. The semiconductor device according to claim 1, wherein the seal rings are formed so as to continuously surround the device-forming areas respectively in each layer of the multi-layer interconnection, and in the non-blade area of the scribing line area, the dummy wirings and the dummy vias are arranged dispersedly in each layer of the multi-layer interconnection.

8. The semiconductor device according to claim 1, wherein in the first or the second wiring layer, the layout density of the dummy wirings formed in the blade area and that of the dummy wirings formed in the non-blade area are substantially equal.

9. The semiconductor device according to claim 1, wherein in the blade area, a dummy via is not formed in any of the layers in the multi-layer interconnection.

10. The semiconductor device according to claim 1, wherein in each of the wiring layers in the multi-layer interconnection, dummy wirings are formed in the blade area and the non-blade area, respectively, and the multi-layer interconnection includes also in the non-blade area the configuration of the vertically adjacent dummy wirings being coupled together through dummy vias, but in some layers the vertically adjacent dummy wirings are not coupled together through dummy vias.
